(19) United States
(12) Patent Application Publication
(10) Pub. No.: US 2015/0137128 A1
(43) Pub. Date: May 21, 2015

(54) THIN-FILM TRANSISTOR ARRAY SUBSTRATE AND METHOD FOR REPAIRING THE SAME

(71) Applicant: SHENZHEN CHINA STAR OPTOELECTRONICS TECHNOLOGY CO, LTD., Shenzhen, Guangdong (CN)

(72) Inventors: Zhiguang Yi, Shenzhen (CN); Tsung Lung Chang, Shenzhen (CN)

(21) Appl. No.: 14/241,392

(22) PCT Filed: Jan. 17, 2014
(86) PCT No.: PCT/CN2014/070838

§ 371 Date: Feb. 26, 2014

(30) Foreign Application Priority Data
Nov. 21, 2013 (CN) 201310593815.0

(51) Int. Cl. H01L 27/12

(52) U.S. Cl. CPC H01L 27/1296; H01L 27/1255; H01L 27/124
USPC 257/71; 438/4

(57) ABSTRACT

The present disclosure disclosed a thin-film transistor array substrate and a method for repairing the same. The array substrate comprises: a substrate; a plurality of common lines, configured on the substrate; a plurality of scan lines and data lines, arranged on the substrate with each scan line and data line perpendicular to each other, to form a plurality of pixel areas; a plurality of pixel elements including a main pixel electrode, a sub pixel electrode, and a charge sharing unit including a charge capacitor which provides a voltage difference between the main pixel electrode and the sub pixel electrode. When the charge capacitor is defective, an upper electrode or a lower electrode of the defective capacitor is disconnected from a circuit connected thereto. The method enables the repairing process faster and simpler, which is different from the traditional repairing means. The pixel element repaired can still work normally.

### FIELD OF THE INVENTION

The present disclosure relates to a liquid crystal display technology, and particularly, to a thin-film transistor array substrate of a large-sized liquid crystal display panel and a method for repairing the same.

### BACKGROUND OF THE INVENTION

A thin-film transistor liquid crystal display (TFT LCD) panel has become mainstream product on the current market due to its excellent performance. The TFT LCD panel generally consists of a thin-film transistor array substrate, a color filter substrate, and a liquid crystal layer, wherein a plurality of pixel elements are arranged on the thin-film transistor array substrate in the form of an array, and each pixel element at least includes a thin-film transistor and a pixel electrode corresponding to the thin-film transistor. The thin-film transistor, acting as a switching element for starting the work of the pixel element, is connected to a scan line and a data line, so as to apply the voltage of a data signal to the corresponding pixel electrode under the drive of a scan signal, for display of image information. Moreover, the partial area of the pixel electrode lies upon the scan line or a common line of the substrate, with the overlapped portion acting as a storage capacitor Cst, which is used for maintaining the voltage of the data signal applied to the pixel electrode, so as to keep the picture display quality.

In the manufacturing process of the present mainstream thin-film transistor array substrate, an upper electrode is also configured between each pixel electrode and the common line corresponding to the pixel electrode. There is a first dielectric layer placed between the upper electrode and the corresponding common line to provide electrical isolation therebetween. Meanwhile, there is also a second dielectric layer placed between the upper electrode and the corresponding pixel electrode, with a contact window arranged at the corresponding position of the second dielectric layer, thereby the upper electrode is electrically connected to the corresponding pixel electrode through the contact window. When particles fall onto the dielectric layer of the storage capacitor due to defects in the manufacturing process or other factors, the leakage or even failure of the storage capacitor will occur, which caused the abnormal display of the pixel element, and thus influencing the picture display quality.

Therefore, it is necessary to perform local repairing on the thin-film transistor array substrate with the above-mentioned problems. The present common method for repairing the substrate is to cut off the electric connection around a defective capacitor, so that the pixel element where the defective capacitor is located fails and becomes a dark spot. This repairing method is quite fussy for a large-sized TFT LCD panel which gradually becomes the market mainstream at present. This is because the large-sized liquid crystal display panel mostly adopts a charge sharing technology for solving a problem of color shift due to a wide viewing angle. That is, each pixel element is provided with at least three thin-film transistors for adjusting the voltage difference between a main pixel electrode area I and a sub pixel electrode area II to eliminate the color shift. When the particles fall onto the dielectric layer of the storage capacitor, the electric connection between the storage capacitor and the pixel electrode needs to be totally cut off, and two poles of the storage capacitor are fused, so that the pixel element where the defective capacitor is located fails and becomes the dark spot. This traditional method is fussy in operation and needs at least four times of fusion and five times of cut-off (as shown in FIG. 1), so that the method is time and energy consuming. Moreover, since the pixel element completely fails and becomes the dark spot, the picture imaging quality is affected.

Thus, a simpler and reasonable method is urgently needed to substitute the above-mentioned traditional method. Inventors of the present disclosure obtain a simpler and reasonable method for repairing the substrate through repeated experimental research just based on practical experience in design and manufacture of liquid crystal display panels and related professional knowledge. The pixel element repaired according to the method can be reused, with low influence on the display.

### SUMMARY OF THE INVENTION

Aiming at the above-mentioned problems, the present disclosure provides a thin-film transistor array substrate and a method for repairing the same. A pixel element repaired according to the method can be reused, with low influence on the picture imaging quality.

The present disclosure provides a method for repairing a thin-film transistor array substrate, wherein the array substrate includes:

a substrate;

a plurality of common lines, configured on the substrate;

a plurality of scan lines and data lines, arranged on the substrate with each scan line and data line perpendicular to each other, to form a plurality of pixel areas;

a plurality of pixel elements, configured in the pixel areas, wherein each pixel element includes:

a main pixel electrode and a sub pixel electrode, and

a charge sharing unit, electrically connected to the main pixel electrode and the sub pixel electrode, and including a charge capacitor which provides a voltage difference between the main pixel electrode and the sub pixel electrode;

when the charge capacitor is defective, the method includes the step of:

disconnecting an upper electrode or a lower electrode of the defective capacitor from a circuit connected thereto to form electric insulation.

According to an embodiment of the present disclosure, each pixel element of the array substrate is electrically connected with two scan lines and one data line, wherein,

the main pixel electrode and the sub pixel electrode are configured to receive a data signal from the data line under a scan signal of the first scan line respectively so as to have the same voltage; and

the charge sharing unit is configured to change the voltage of the sub pixel electrode under the drive of a scan signal of the second scan line, so that the voltage of the sub pixel electrode is different from the voltage of the main pixel electrode.

According to an embodiment of the present disclosure, the upper electrode or the lower electrode of the defective capacitor may be disconnected to the surrounding circuit connected thereto by laser.

According to an embodiment of the present disclosure, the upper electrode is a transparent conductive layer.

Further, the upper electrode is connected with the common line.

Moreover, the lower electrode and the data line are formed under one single photomask.

The present disclosure also provides a thin-film transistor array substrate, characterized by including:

a substrate;

a plurality of common lines, configured on the substrate;

a plurality of scan lines and data lines, arranged on the substrate with each scan line and data line perpendicular to each other, to form a plurality of pixel areas;

a plurality of pixel elements, configured in the pixel areas, wherein each pixel element includes:

a main pixel electrode and a sub pixel electrode, and

a charge sharing unit, electrically connected to the main pixel electrode and the sub pixel electrode, and including a charge capacitor which provides a voltage difference between the main pixel electrode and the sub pixel electrode, wherein when the charge capacitor is defective, an upper electrode or a lower electrode of the defective capacitor is disconnected from a circuit connected thereto to form electric insulation.

According to an embodiment of the present disclosure, each pixel element of the array substrate is electrically connected with two scan lines and one data line, wherein

the main pixel electrode and the sub pixel electrode are configured to receive a data signal from the data line under the drive of a scan signal of the first scan line respectively so as to have the same voltage;

the charge sharing unit is configured to change the voltage of the sub pixel electrode under the drive of a scan signal of the second scan line, so that the voltage of the sub pixel electrode is different from the voltage of the main pixel electrode.

Specifically, the charge sharing unit includes:

a thin-film transistor, the gate of which is electrically connected with the second scan line, the drain of which is electrically connected to the sub pixel electrode, and the source of which is coupled with the common line so as to form the charge capacitor.

Moreover, the source of the thin-film transistor of the charge sharing unit may also be coupled to the main pixel electrode to form the other charge capacitor.

Compared with the prior art, the present disclosure has the following obvious advantages and beneficial effects:

1, the method provided in the present disclosure can avoid leakage of the storage capacitor due to particles or breakage of a dielectric layer, so that it can be widely applied;

2, the method provided in the present disclosure is easy and fast to operate, and has relatively low influence on the display effect;

3, in the manufacturing process of the thin-film transistor array substrate provided in the present disclosure, the lower electrode of the charge capacitor may be manufactured in the same procedure as the drain, the source of the thin-film transistor, and the data line so that they belong to a second metal layer (M2), and the upper electrode of the charge capacitor may be manufactured in the same procedure as the common line so that they belong to a first metal layer (M1), which result in that the manufacturing cost is relatively low.

### BRIEF DESCRIPTION OF THE DRAWINGS

FIG. 1 is a schematic diagram of a common method for repairing a thin-film transistor array substrate in the prior art;

FIG. 2 is an equivalent circuit diagram of a 2G1D pixel element structure on an array substrate of a liquid crystal display panel in the prior art; and

FIG. 3 is a schematic diagram of an embodiment of a method for repairing a thin-film transistor array substrate provided in the present disclosure.

### DETAILED DESCRIPTION OF THE EMBODIMENTS

To further illustrate the objectives, technical solutions and technical effects of the present disclosure, the principle and embodiments of a method provided herein and better technical effects compared with the prior art will be introduced in detail below with reference to an equivalent circuit diagram of a thin-film transistor array substrate of a large-sized liquid crystal display panel and a 2G1D pixel element structure (a pixel element is electrically connected with two scan lines and one data line) arranged on the array substrate in the prior art. It should be noted that although the present disclosure is illustrated with respect to the 2G1D pixel element structure, the present disclosure should not be limited thereto. The structures of pixel elements designed by different manufacturers are not completely the same and have a plurality of variants, for example, there is also a 1G2D pixel element structure (a pixel element is electrically connected with one scan line and two data lines). Accordingly, any modifications and variations made to the implementation forms and details of the technical solutions by any one skilled in the art to which the present disclosure pertains without departing from the sprit disclosed in the present disclosure are within the protection scope of the present disclosure.

FIG. 2 shows an equivalent circuit diagram of a pixel element arranged on an array substrate of a large-sized liquid crystal display panel. By adopting a charge sharing technology, pixel electrodes of the pixel element are divided into a main pixel electrode area I, a sub pixel electrode area II, and a charge sharing unit, wherein

The main pixel electrode area I includes a thin-film transistor T1, the gate of which is electrically connected with a scan line Scan1, the source of which is electrically connected with a data line Data, and the drain of which is electrically connected with the main pixel electrode area 1. A storage capacitor Cst1 and a liquid crystal capacitor Clc1 are formed between an upper electrode (not shown in FIG. 2) electrically connected with the main pixel electrode area I and a corresponding common line Com.

The sub pixel electrode area II includes a thin-film transistor T2, the gate of which is electrically connected with the scan line Scan1, the source of which is electrically connected with the data line Data, and the drain of which is electrically connected with the sub pixel electrode area II. A storage capacitor Cst2 and a liquid crystal capacitor Clc2 are formed between the upper electrodes (not shown in FIG. 2) electrically connected with the sub pixel electrode area II and the corresponding common line Corn.

The charge sharing unit includes a thin-film transistor T3, the gate of which is electrically connected with a scan line Scan2, the drain of which is electrically connected with the pixel electrode area II, wherein, a first charge capacitor Ccs1 is formed between the source of the thin-film transistor T3 and the upper electrode electrically connected with the main pixel electrode area I, and a second charge capacitor Ccs2 is formed between the source of the thin-film transistor T3 and the corresponding common line Corn.

The basic principle of the charge sharing technology is: firstly, when the scan line Scan1 transmits a scan signal, the drains and the sources of the thin-film transistor T1 and the thin-film transistor T2 are turned on, so that the voltages of the main pixel electrode area I and the sub pixel electrode area II reach the same potential under a data signal transmitted by the data line Data; and then, when the scan line Scan2 transmits a scan signal, the drains and the sources of the thin-film transistor T1 and the thin-film transistor T2 are turned off, meanwhile, the drain and the source of the thin-film transistor T3 are turned on, so that charges on the sub pixel electrode area II are transferred to the common line Com through the second charge capacitor Ccs2, the voltage of the sub pixel electrode area II and the voltage of the main pixel electrode area I produce a voltage difference, and then liquid crystal in the sub pixel electrode area II and liquid crystal in the main pixel electrode area I deflect at different deflecting angles to achieve the technical effect of multi-domain display compensated large view angle color shift.

As discussed in the background, when particles fall onto a dielectric layer of one storage capacitor or the dielectric layer of the storage capacitor is broken, a leakage phenomenon occurs in the storage capacitor, which results in the abnormal display of the pixel element and poor quality of display. At this moment, the abnormal pixel element needs to be repaired. As far as the present repairing means, electric connections between the thin-film transistor T1 and the data line Data, between the thin-film transistor T1 and the main pixel electrode area I, between the thin-film transistor T2 and the data line Data, between the thin-film transistor T2 and the sub pixel electrode area II, and between the thin-film transistor T3 and the sub pixel electrode area II in the pixel element need to be cut off by using laser, and the upper electrode electrically connected with the main pixel electrode area I and the upper electrode electrically connected with the sub pixel electrode area II are fused with the corresponding common line by laser respectively. The whole process is fussy, time consuming, and energy consuming. Moreover, the sub pixel electrode area II which was supposed to work normally will be affected and become a dark spot.

To solve the above problem, certain improvement is made to the traditional method by the skilled of the present disclosure based on years of accumulated rich experience and professional knowledge in design and manufacture of liquid crystal panels, so that the method has practicability.

Aiming at the condition of electric leakage or failure of the second charge capacitor Ccs2 in the pixel element due to the particles or breakage, the present disclosure proposes a new method for repairing the substrate, namely a method of only removing the second charge capacitor Ccs2. According to the principle of the above-described charge sharing technology, after removing the second charge capacitor Ccs2, if the scan line Scan2 transmits the scan signal, the drain and the source of the thin-film transistor T3 are turned on. In this case, although only the first charge capacitor Ccs1 is valid, the whole pixel element can still work in the normal manner, except for having the problem of large view angle color shift. However, the problem has low influence on the display function of the whole pixel element, and it is difficult for naked eyes to distinguish the variations of previous and later display effects. This method enables the repairing process faster and simpler, which is different from the traditional repairing means. Furthermore, the repaired pixel element still can display images. Therefore, the method has great improvement on implementation or technical effects, and thus can be widely used.

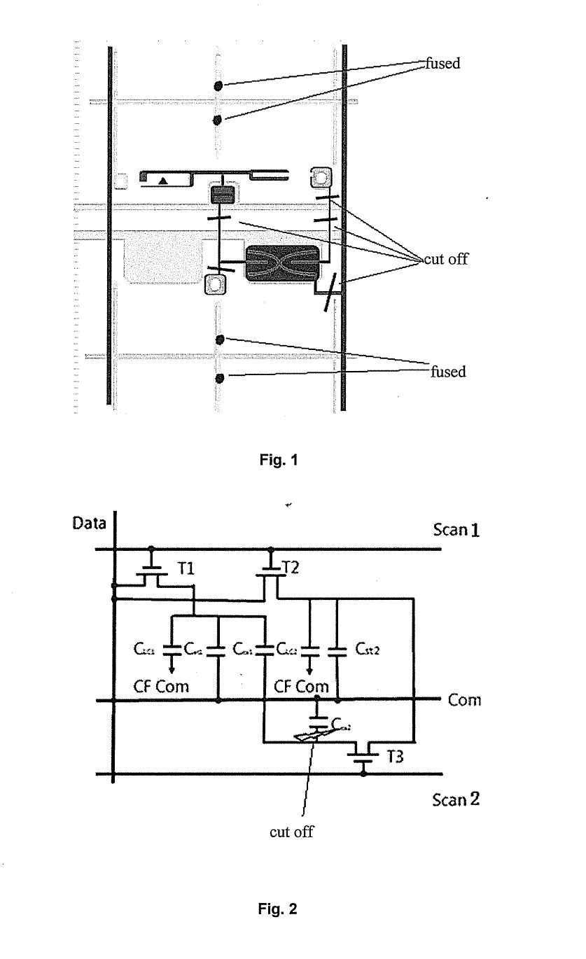

Still taking the embodiment described in the background section as an example, as shown in FIG. 1, in the manufacturing process of the array substrate of the large-sized liquid crystal display panel adopting the charge sharing technology, the lower electrode of the second charge capacitor Ccs2 is formed together with the source and the drain of each thin-film transistor and the data line, so that they belong to the second metal layer (M2). The upper electrode of the second charge capacitor Ccs2 is formed together with the common line, so that they belong to the first metal layer (M1). The second charge capacitor Ccs2 may be of a metal-insulated-metal structure formed by a metal wire extended from the source of the thin-film transistor T3 and a metal wire extended from the common line Com. In this case, this embodiment may adopt the two methods below to remove the invalid second charge capacitor Ccs2:

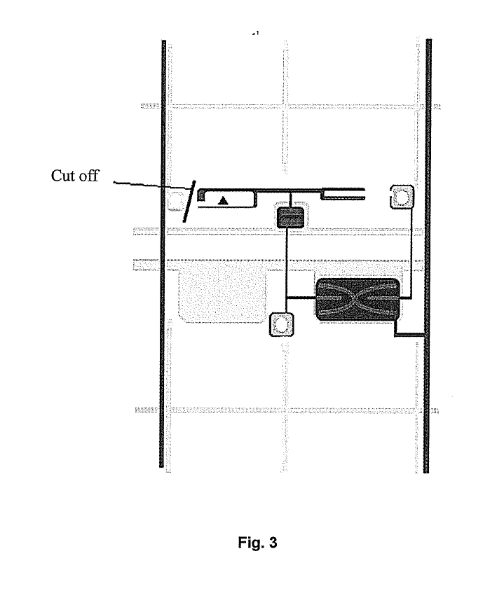

disconnecting the metal wire connected between the lower electrode of the second charge capacitor Ccs2 and the source of the thin-film transistor T3 by using laser; or disconnecting the metal wire connected between the upper electrode of the second charge capacitor Ccs2 and the common line Com by using laser (shown in FIGS. 2 and 3).

The foregoing descriptions are merely preferred embodiments of the present disclosure. For example, the structure of the pixel element adopting the charge sharing technology may be in multiple variation forms, and is not limited to the structural form consisting of three thin-film transistors.

The embodiments have been described above only for facilitating the understanding of the present disclosure, but the present disclosure is not limited to this. Any changes or alternatives conceived by the skilled ones in the art after reading the content disclosed herein will fall within the scope of the present disclosure. Accordingly, the scope of the present disclosure will be defined in the accompany claims.

1. A method for repairing a thin-film transistor array substrate, the array substrate comprising:
a substrate;
a plurality of common lines, configured on the substrate;
a plurality of scan lines and data lines, arranged on the substrate with each scan line and data line perpendicular to each other, to form a plurality of pixel areas;
a plurality of pixel elements, configured in the pixel areas, wherein each pixel element includes: a main pixel electrode and a sub pixel electrode; and a charge sharing unit, electrically connected to the main pixel electrode and the sub pixel electrode, and including a charge capacitor which provides a voltage difference between the main pixel electrode and the sub pixel electrode;
wherein, when the charge capacitor is defective, the method includes the step of disconnecting an upper electrode or a lower electrode of the defective capacitor from a circuit connected thereto to form electric insulation.

2. The method of claim 1, wherein, each pixel element of the array substrate is electrically connected with two scan lines and one data line, and wherein, the main pixel electrode and the sub pixel electrode are configured to receive a data signal from the data line under a scan signal of the first scan line respectively so as to have the same voltage; and
the charge sharing unit is configured to change the voltage of the sub pixel electrode under the drive of a scan signal of the second scan line, so that the voltage of the sub pixel electrode is different from that of the main pixel electrode.

3. The method of claim 1, wherein, the upper or lower electrode of the defective capacitor is disconnected from the surrounding circuit connected thereto by laser.

4. The method of claim 2, wherein, the upper or lower electrode of the defective capacitor is disconnected from the surrounding circuit connected thereto by laser.

5. The method of claim 1, wherein, the upper electrode is a transparent conductive layer.

6. The method of claim 2, wherein, the upper electrode is a transparent conductive layer.

7. The method of claim 5, wherein, the upper electrode is connected with the common line.

8. The method of claim 6, wherein, the upper electrode is connected with the common line.

9. The method of claim 1, wherein, the lower electrode and the data line are formed under one single photomask.

10. The method of claim 2, wherein, the lower electrode and the data line are formed under one single photomask.

11. A thin-film transistor array substrate, comprising:
a substrate;
a plurality of common lines, configured on the substrate; and
a plurality of scan lines and data lines, arranged on the substrate with each scan line and data line perpendicular to each other, to form a plurality of pixel areas;
a plurality of pixel elements, configured in the pixel areas, wherein each pixel element includes:
a main pixel electrode and a sub pixel electrode, and
a charge sharing unit, electrically connected to the main pixel electrode and the sub pixel electrode, and including a charge capacitor which provides a voltage difference between the main pixel electrode and the sub pixel electrode, wherein when the charge capacitor is defective, an upper electrode or a lower electrode of the defective capacitor is disconnected from a circuit connected thereto to form electric insulation.

12. A thin-film transistor array substrate, with each pixel element of the array substrate being electrically connected with two scan lines and one data line, wherein
the main pixel electrode and the sub pixel electrode are configured to receive a data signal from the data line under the drive of a scan signal of the first scan line respectively so as to have the same voltage; and
the charge sharing unit is configured to change the voltage of the sub pixel electrode under the drive of a scan signal of the second scan line, so that the voltage of the sub pixel electrode is different from the voltage of the main pixel electrode.

13. The thin-film transistor array substrate of claim 12, wherein, the charge sharing unit includes a thin-film transistor, the gate of which is electrically connected with the second scan line, the drain of which is electrically connected to the sub pixel electrode, and the source of which is coupled with the common line, so as to form the charge capacitor.

14. The thin-film transistor array substrate of claim 13, wherein, the source of the thin-film transistor of the charge sharing unit is also coupled to the main pixel electrode, to form another charge capacitor.

15. The thin-film transistor array substrate of claim 11, wherein, the upper electrode is a transparent conductive layer.

16. The thin-film transistor array substrate of claim 12, wherein, the upper electrode is a transparent conductive layer.

17. The thin-film transistor array substrate of claim 11, wherein, the upper electrode is connected with the common line.

18. The thin-film transistor array substrate of claim 12, wherein, the upper electrode is connected with the common line.

19. The thin-film transistor array substrate of claim 11, wherein, the lower electrode and the data line are formed under one single photomask.

20. The thin-film transistor array substrate of claim 12, wherein, the lower electrode and the data line are formed under one single photomask.
